(19) United States
(12) Patent Application Publication
(10) Pub. No.: US 2012/0320519 A1
(43) Pub. Date: Dec. 20, 2012

(54) STORAGE DEVICE ASSEMBLY

(75) Inventors: CHIA-KANG WU, Tu-Cheng (TW); YAO-CHUNG CHEN, Tu-Cheng (TW); CHIEH-CHEN CHEN, Tu-Cheng (TW); LI-PING CHEN, Tu-Cheng (TW)

(73) Assignee: HON HAI PRECISION INDUSTRY CO., LTD., Tu-Cheng (TW)

(21) Appl. No.: 13/366,587

(22) Filed: Feb. 6, 2012

(30) Foreign Application Priority Data
Jun. 20, 2011 (TW) 100121360

(51) Int. Cl. H05K 5/02

(52) U.S. Cl. 361/679.33

(57) ABSTRACT

A storage device assembly includes a drive bracket and a plurality of storage devices accommodated in the drive bracket. The drive bracket includes a base plate, a pair of first side plates extending from a first pair of opposite side edges of the base plate, a pair of second side plates extending from a second pair of opposite side edges of the base plate, and a plurality of securing plates substantially perpendicularly attached to at least one of the pair of first side plates. Each of the plurality of storage devices includes a protrusion. A plurality of securing members is attached to each of the plurality of securing plates. Each of the plurality of securing members abuts the protrusion for preventing a corresponding one of the plurality of storage devices moving in a first direction that is substantially perpendicular to the pair of first side plates.

### BACKGROUND

1. Technical Field

The present disclosure relates to a storage device assembly, and particularly to a storage device assembly for a computer or a server.

2. Description of Related Art

Typical storage device assemblies for computers or servers include a drive bracket, at least one storage device mounted in the drive bracket, and a securing member attached to an outside of the drive bracket. A guiding slot is defined in each side panel of the drive bracket. A post extends from each side wall of the storage device. When the at least one storage device is moving in or out of the drive bracket, the post is sliding along the guiding slot. The securing member is movable or rotatable between a lock position, wherein the post is blocked by the securing member to lock the at least one storage device in the drive bracket, and an unlock position, wherein the post is released by the securing member to unlock the at least one storage device. However, the typical storage device assemblies can mount only a few storage devices.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of one embodiment of a storage device assembly.

FIG. 2 illustrates a securing plate and a plurality of securing members of the storage device assembly of FIG. 1.

FIG. 3 illustrates a plurality of storage devices and a pair of securing plates of the storage device assembly of FIG. 1.

FIG. 4 is an assembled view of the storage device assembly of FIG. 1.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean at least one.

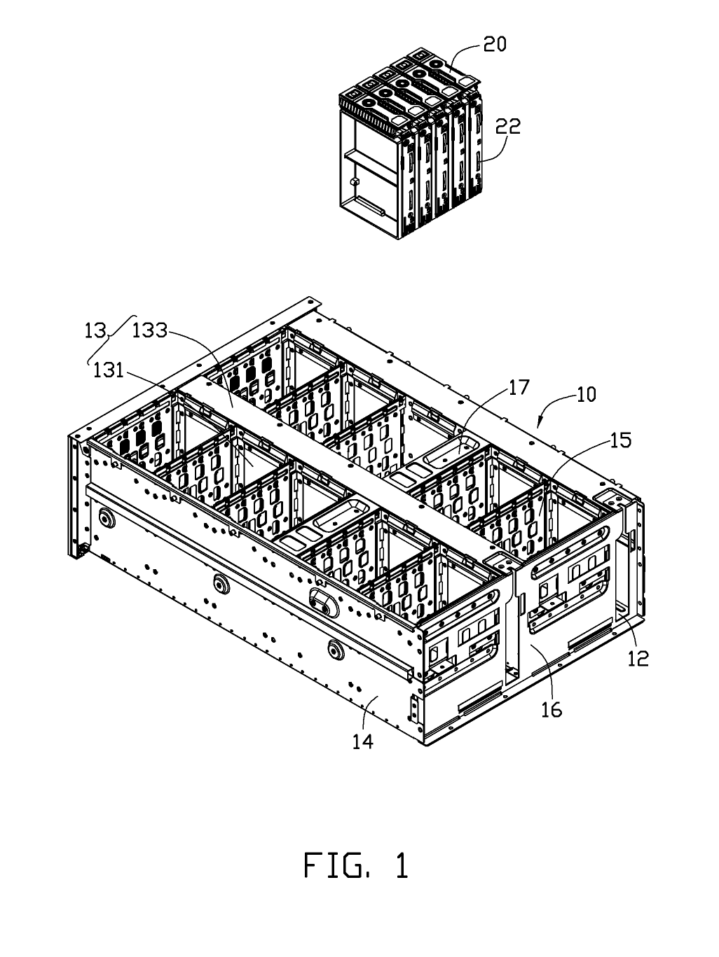

Referring to FIG. 1, an embodiment of a storage device assembly includes a plurality of storage devices 20 and a drive bracket 10 for accommodating the plurality of storage devices 20. Each of the plurality of storage devices 20 includes a pair of sidewalls (not labeled). An arc-shaped longitudinal protrusions 22 protrudes from each of the pair of sidewalls. In one embodiment, each of the plurality of storage devices 20 is a hard disk drive.

The drive bracket 10 includes a base plate 12, a pair of first side plates 14, and a pair of second side plates 16 extending substantially perpendicularly from the base plate 12. In the illustrated embodiment, the pair of first side plates 14 extends from long edges of the base plate 12, and the pair of second side plates 16 extends from short edges of the base plate 12. The bracket 10 also includes an intermediate dividing plate 13 located between the pair of first side plates 14. The intermediate diving plate 13 includes a main plate 131 substantially parallel to the pair of first side plates 14 and a top flange 133 extending substantially perpendicularly from a top edge of the main plate 131. The intermediate dividing plate 13 can divide an accommodating space in the drive bracket 10 into two equal-sized spaces. The bracket 10 also includes a plurality of securing plates 15 and a separating plate 17 located in each of the two equal-sized spaces. The separating plate 17 further divides each of the two equal-sized spaces into a smaller accommodating space and a larger accommodating space. In one embodiment, there are three equally spaced securing plates 15 installed in the smaller accommodating space, and there are four equally spaced securing plates 15 installed in the larger accommodating space. In the smaller accommodating space, one of the plurality of securing plates 15 divides the smaller accommodating space into two equally sized accommodating spaces. In the larger accommodating space, two of the plurality of securing plates 15 divides the larger accommodating space into three equally sized accommodating spaces. Each accommodating space between two adjacent ones of the plurality of securing plates 15 can accommodate one or more storage devices 20 therein.

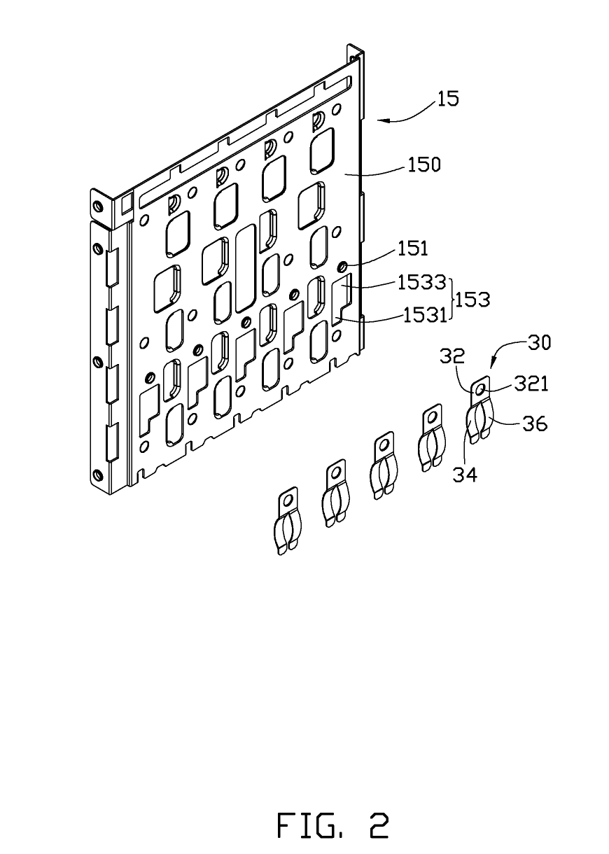

Referring to FIGS. 1 and 2, a plurality of mounting posts 151 protrudes substantially perpendicularly from a plate wall 150 of each of the plurality of securing plates 15. A plurality of openings 153 is defined in the plate wall 150 of each of the plurality of securing plates 15 and located below the plurality of mounting posts 151. Each of the plurality of openings 153 includes a first cutout 1531 and a second cutout 1533 communicating with the first cutout 1531. In one embodiment, a longitudinal length of the first cutout 1531 is greater than that of the second cutout 1533, thereby forming an L-shaped opening 153. A plurality of securing members 30 can be attached to the plurality of mounting posts 151. Each of the plurality of securing members 30 includes a securing piece 32, a first resisting piece 34 extending downward from one half of a lower edge of the securing piece 32, and a second resisting piece 36 extending downward from the other half of the lower edge of the securing pieces 32. The first resisting piece 34 and the second resisting piece 36 can be arc-shaped and protrude in opposite directions. A securing hole 321 is defined in the securing piece 32. A width of each of the first resisting piece 34 is substantially equal to that of first cutout 1531.

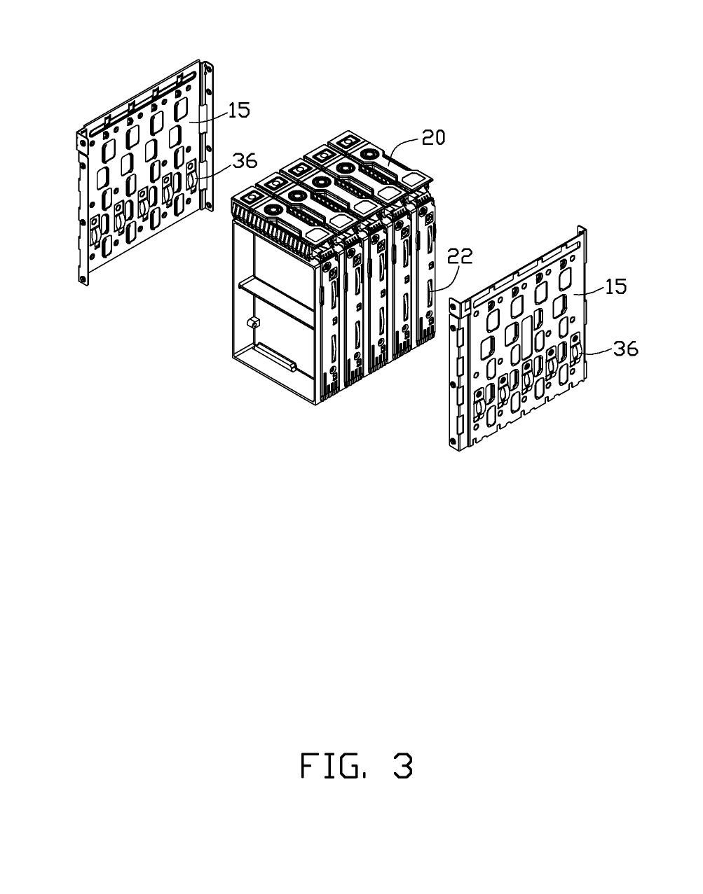

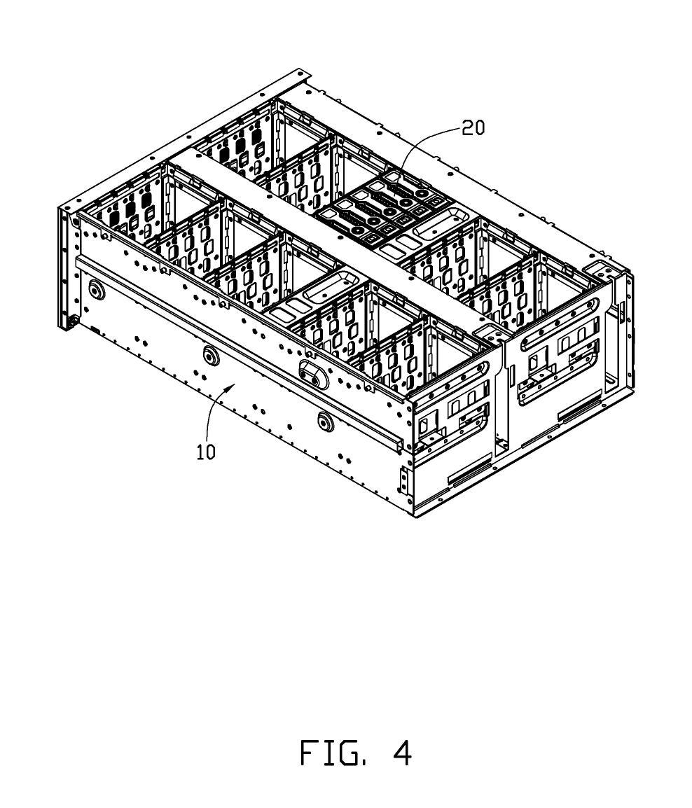

Referring to FIGS. 3 and 4, in assembly, each of the plurality of mounting posts 151 extends into the securing hole 321 to secure the plurality of securing members 30 to the plurality of mounting posts 151. The first resisting piece 34 extends through the first cutout 1531. A lower end of the second resisting piece 36 abuts the plate wall 150 of the plurality of securing plates 15 and the arc-shaped portion of the second resisting piece 36 extends partly through the second cutout 1533. The first resisting piece 34 and the second resisting piece 36 extend from opposite sides of the plate wall 150 of the plurality of securing plates 15. The plurality of storage devices 20 is inserted into the accommodating space between two adjacent securing plates 15 along an inserting direction until the plurality of storage devices 20 is contacting the base plate 12. The arc-shaped longitudinal protrusion 22 at a first side of each of the plurality of storage devices 20 abuts the first resisting piece 34 at the first side. The arc-shaped longitudinal protrusion 22 at a second side of each of the plurality of storage devices 20 abuts the second resisting piece 36 at the second side. Therefore, each of the plurality of storages devices 20 is prevented from moving perpendicular to the inserting direction and held by forces exerted by the first and second resisting pieces 34, 36 against the arc-shaped longitudinal protrusions 22.

In one embodiment, each accommodating space between two adjacent securing plates 15 can accommodate five storage devices 20 therein. Each of the plurality of securing members 30 can abut two storage devices in two adjacent accommodating spaces and limit movement of the two storage devices because the first resisting piece 34 and the second resisting piece 36 are located at opposite sides of the securing plate 15.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A storage device assembly comprising:
a drive bracket comprising a base plate, a pair of first side plates extending from a first pair of opposite side edges of the base plate, a pair of second side plates extending from a second pair of opposite side edges of the base plate, and a plurality of securing plates attached substantially perpendicularly to at least one of the pair of first side plates, wherein an accommodating space is located between two adjacent securing plates of the plurality of securing plates;
a plurality of storage devices accommodated in the accommodating space, each of the plurality of storage devices comprising a pair of sidewalls and a protrusion protruding from each of the pair of sidewalls; and
a plurality of securing members attached to each of the plurality of securing plates, each of the plurality of securing members abutting the protrusion for preventing a corresponding storage device of the plurality of storage devices moving in a first direction that is substantially perpendicular to the pair of first side plates.

2. The storage device assembly of claim 1, wherein the drive bracket further comprises an intermediate dividing plate connected between the pair of second side plates, the each of the plurality of securing plates is located between one of the pair of first side plates and the intermediate dividing plate.

3. The storage device assembly of claim 2, wherein the intermediate dividing plate comprises a main plate substantially parallel to each of the pair of first side plates and a top flange extending substantially perpendicularly from a top edge of the main plate.

4. The storage device assembly of claim 1, wherein a securing hole is defined in the each of the plurality of securing members, the each of the plurality of securing plates comprises a plate wall and a mounting post protruding from the plate wall and extending into the securing hole.

5. The storage device assembly of claim 4, wherein the each of the plurality of securing members comprises a securing piece, a first resisting piece extending from a first half of a lower edge of the securing piece, and a second resisting piece extending from a second half of the lower edge of the securing piece; the securing hole is defined in the securing piece.

6. The storage device assembly of claim 5, wherein the first resisting piece and the second resisting piece have the same shape and protrude from opposite sides of the securing piece.

7. The storage device assembly of claim 6, wherein an opening is defined in the plate wall and located below the mounting post, the first resisting piece extends through the opening, and the second resisting piece abuts the plate wall.

8. The storage device assembly of claim 7, wherein the opening comprises a first cutout and a second cutout connected with the first cutout, a length of the first cutout along a longitudinal direction perpendicular to the base plate is greater than that of the second cutout, and a width of the first cutout is substantially equal to that of the first resisting piece.

9. The storage device assembly of claim 1, wherein the plurality of storage devices are movable in a direction substantially perpendicular to the base plate to move into or out from the drive bracket.

10. A storage device assembly comprising:
a drive bracket comprising a base plate, a pair of first side plates extending from a first pair of opposite side edges of the base plate, a pair of second side plates extending from a second pair of opposite side edges of the base plate, and a plurality of securing plates attached substantially perpendicularly to at least one of the pair of first side plates;
a plurality of storage devices accommodated in the drive bracket, each of the plurality of storage devices comprising a pair of sidewalls and a protrusion protruding from each of the pair of sidewalls; and
a plurality of securing members attached to each of the plurality of securing plates, each of the plurality of securing members comprising a first resisting piece and a second resisting piece, wherein one of the first resisting piece and the second resisting piece abuts the protrusion for preventing a corresponding storage device of the plurality of storage devices moving in a first direction that is substantially perpendicular to the pair of first side plates.

11. The storage device assembly of claim 10, wherein the drive bracket further comprises an intermediate dividing plate connected between the pair of second side plates, and each of the plurality of securing plates is located between one of the pair of first side plates and the intermediate dividing plate.

12. The storage device assembly of claim 11, wherein the intermediate dividing plate comprises a main plate substantially parallel to each of the pair of first side plates and a top flange extending substantially perpendicularly from a top edge of the main plate.

13. The storage device assembly of claim 10, wherein the each of the plurality of securing members further comprises a securing piece connected to the first resisting piece and the second resisting piece, a securing hole is defined in the securing piece, and the each of the plurality of securing plates comprises a plate wall and a mounting post protruding from the plate wall and extending into the securing hole.

14. The storage device assembly of claim 13, wherein the first resisting piece extends from a first half of a lower edge of the securing piece, and the second resisting piece extends from a second half of the lower edge of the securing piece.

15. The storage device assembly of claim 14, wherein central portions of the first resisting piece and the second resisting piece are arc-shaped and protrude in opposite directions.

16. The storage device assembly of claim 15, wherein an opening is defined in the plate wall and located below the mounting post, the first resisting piece extends through the opening, and the second resisting piece abuts the plate wall.

17. The storage device assembly of claim 10, wherein the protrusion of the storage devices is an arc-shaped slim protrusion.

18. The storage device assembly of claim 10, wherein the intermediate dividing plate divides an accommodating space into two equal-sized spaces, the drive bracket further comprises a separating plate located at each of the two equal-sized spaces, and the separating plate is connected to and located between one of the pair of first side plates and the intermediate dividing plate and divides each of the two equal-sized spaces into a smaller accommodating space and a larger accommodating space.

19. The storage device assembly of claim 18, wherein three equal-spaced securing plates of the plurality of securing plates are located in the smaller accommodating space, and four equal-spaced securing plates of the plurality of securing plates are located in the larger accommodating space.
